(19) United States
(12) Patent Application Publication
(10) Pub. No.: US 2013/0264680 A1
(43) Pub. Date: Oct. 10, 2013

(54) NANOLAMINATES OF Al2O3/TiO2 WITH GIANT DIELECTRIC CONSTANT LOW-LEAKAGE-LOW LOSS-EXTENDED FREQUENCY OPERATION FOR NEW-GENERATION NANOELECTRONICS AND ENERGY STORAGE DEVICES

(71) Applicants: Orlando H. AUCIELLO, Bolingbrook, IL (US); Bo-Kuai LAI, Woodridge, IL (US); Geunhee LEE, Naperville, IL (US); Ram S. KATIYAR, San Juan, PR (US)

(72) Inventors: Orlando H. AUCIELLO, Bolingbrook, IL (US); Bo-Kuai LAI, Woodridge, IL (US); Geunhee LEE, Naperville, IL (US); Ram S. KATIYAR, San Juan, PR (US)

(73) Assignee: UChicago Argonne LLC

(21) Appl. No.: 13/440,716

(22) Filed: Apr. 5, 2012

(51) Int. Cl. B32B 7/02; H01L 29/02; B82Y 30/00

(52) U.S. Cl. 257/532; 428/216; 257/E29.002; 977/755; 977/948

(57) ABSTRACT

The invention relates generally to a nanolaminate structure involving Al₂O₃ thin films as a main component. The nanolaminate is used between a top electrode and a bottom electode to form a capacitor. The naonolaminate layer comprises alternating layers of Al₂O₃ and TiO₂ and an interfacial layer.

### STATEMENT OF GOVERNMENT INTEREST

The United States Government claims certain rights in this invention pursuant to Contract No. W-31-109-ENG-38 between the United States Government and the University of Chicago and/or pursuant to DE-AC02-06CH11357 between the United States Government and UChicago Argonne, LLC representing Argonne National Laboratory.

### FIELD OF THE INVENTION

The invention relates generally to a nanolaminate structure involving Al₂O₃ thin films as a main component. More particularly, the invention relates to a nanolaminate structure and method of manufacture of an Al₂O_{3/}TiO₂ layered structure with selected placement of an Al₂O₃, layer and in some cases other oxides layers, at the interface of the Al₂O₃-based nanolaminate structure with a metallic top and/or bottom contact layer to provide a capacitor-like structure.

### BACKGROUND OF THE INVENTION

Extensive basic and applied research is currently being performed in several industrial, national, and university laboratories around the world to develop next-generation low voltage, low energy consumption, high efficiency integrated circuits for advanced microelectronic devices. The heart of every integrated circuit, thus microelectronic devices, is the transistor. The most used transistor scheme in current microelectronic devices is the metal-oxide-semiconductor field-effect-transistor (MOSFET).

For decades, the key element enabling the scaling of the Si-based MOSFET has been the material properties (and resultant electrical properties) associated with the amorphous SiO₂ layer used as a gate oxide. The use of the amorphous SiO₂ gate oxide layer offered key advantages in the processing and operation of complementary metal-oxide-semiconductor (CMOS) devices, including a stable high-quality Si—SiO₂ interface as well as superior electrical isolation properties. Until recently, CMOS devices were based on SiO₂ gates that exhibit defect charge densities of ˜10¹⁰/cm² and mid-bandgap interface state densities of ˜10¹⁰/cm². Despite the attributes of SiO₂, CMOS devices with gate width ≦45 nm required a 1 nm thick SiO₂ layer. The problem with such an extremely thin SiO₂ gate layer was that the electron moving from the source to the drain of the CMOS device were leaked to the gate due to quantum tunneling across the extremely thin SiO₂ gate. Therefore, the SiO₂ gate layer needed to be replaced by a high-dielectric constant (k) layer that could be as thick as 5-10 nm and still keep a high capacitance for a shorter gate because of the higher k value of the dielectric layer, based on the formula for capacitance C=k·A/t, where A and t are the area and thickness of the gate layer, respectively.

For a metal-oxide layer on a p-type semiconductor, when there are no surface electronic states at the oxide-semiconductor interface (see FIG. 1) nor charge accumulation in the oxide, there is no bending of the conduction and valence bands in the semiconductor, and the Fermi level in the metal and the p-type semiconductor lines up. With a small positive bias, V_{g}, applied to the electrode, part of the gate voltage is in the oxide layer (Vₒₓ) and the rest part is in the semiconductor (Vₛ), such that V_{g}=Vₒₓ+Vₛ; and the electric field in the oxide layer is Eₒₓ=Vₒₓ/t, where t is the oxide layer thickness. The presence of a voltage Vₛ in the semiconductor leads to the extraction of electrons from a region in the semiconductor underneath the SiO₂, gate oxide layer resulting in the establishment of a depletion layer. The name of the depletion layer is due to the fact that this layer is depleted of free electrons but populated with fixed negative donor ions of the p-type semiconductor layer. The electric field is expressed as Eₛ=−Q/k, where k is the dielectric constant of the gate layer. Qₛ=−eN_{A}dₚ is the number of negatively charged acceptors per unit area in the depletion layer, where N_{A} is the number of acceptors and dₚ is the width of the depletion layer in the p-type Si.

Increasing V_{G} to a threshold V_{T} that produces enough band bending in the depletion layer results in the appearance of enough free electrons at the semiconductor-oxide interface. The voltage applied between the source and the drain then sweeps the electrons generated in the n-channel, establishing a current that corresponds to the transistor state “on”. If we make the assumption that all the gate voltage above V_{T} is used to accumulate electrons in the depletion layer without increasing its thickness, we can determine the number of free electrons based on the concept of charge on the plates of a capacitor. The value of the capacitance per unit area corresponding to the oxide layer is:

Cₒₓ=kₒₓ/t, (1)

Where t is the oxide thickness and kₒₓ is the dielectric constant of SiO₂. From the general relation of a capacitor VC=Q, we can calculate Qₙ, the charge density per unit area of electrons as:

Qₙ=Cₒₓ(V_{G}−V_{T}), (2)

For a gate voltage V_{G}<V_{T} there is no n-channel connection between the source and drain (i.e., the source-drain current I_{sd}=0 irrespective of the drain voltage V_{D} (this is not exactly true because there is always a small leakage current across the reverse bias p-n junction). For V_{G}>V_{T} and V_{D}<V_{T} the n-type channel between the source and drain behaves like a resistor, for which the resistance R is given by:

R=−L/W μₙQₙe, (3)

where L and W are the length and width of the channel, respectively. The conductance g_{d} of the channel is given by:

g_{d}=dI_{D}/dV_{D}(for V_{G}=constant), (4)

and for the linear regime for which I_{D}=V_{D}/R, g_{d} is given by:

g_{d}=1/R=eμₙQₙW/L, (5)

where μₙ is the mobility of the electrons in the channel between the source and the drain.

The actual physical thickness of a high-k layer needed to achieve the equivalent capacitance of a 1 nm thick SiO₂ layer is give by the following equation:

t_{high-k}=k_{high-k}·t_{eq}/3.9, (6)

so a dielectric layer with a dielectric constant k=16 results in a required physical thickness of ˜4 nm to obtain a t_{eq}=1 nm. Therefore, the higher the dielectric constant k the thicker the gate dielectric layer can be, while still possessing the equivalent oxide thickness of a 1 nm SiO₂ layer.

The HfO₂ layer currently used in the first generation of commercial CMOS devices with gate width ˜45 nm exhibits a dielectric constant k=20. However, for the next generation of CMOS devices with shorter gates, there will be a need for materials with dielectric constant k≧30. A TiAlOₓ alloy has been developed with k=30 and low leakage, providing an alternative gate oxide for nanoscale CMOS devices. However, the TiAlOₓ alloy exhibits a bandgap of about 4 eV, which is still below the 5.5 eV bandgap needed for reliable operation of a high-k dielectric gate layer.

Even, more recently, it has been demonstrated that Al₂O₃/TiO₂ nanolaminates exhibit dielectric constants of up to k=1000. However, the capacitive structures fabricated with those Al₂O₃/TiO₂ nanolaminates on Si substrates exhibit relatively high leakage, and the high dielectric constant of ˜1000 decreased rapidly below about 100 at about 1 kHz, giving only a limited frequency range of operation. The limited operation of the Al₂O₃/TiO₂ nanolaminates without the interfacial Al₂O₃ layer at the top electrode/nanolaminate interface is due to the fact that there is a substantial charge injection into the nanolaminates.

In early 2007, INTEL announced the deployment of HfO₂-based high-k dielectrics in conjunction with a metallic gate for components built on 45 nm CMOS technologies, and shipped it in the 2007 processor series codenamed Penryn. However, although the first generation of nanoscale CMOS devices with high-k dielectric gates are already in the market, the dielectric constant of HfO₂ and most amorphous oxide dielectric known today is much less than 100.

Another critical technological application of the Al₂O₃/TiO₂ nanolaminates can be a new generation of supercapacitors for energy storage in industrial applications and for biocompatible (TiO₂ and Al₂O₃) energy storage capacitors embedded in microchips implantable in humans as part of biomedical devices for restoring sight to blind people, or restoring hearing to deaf people, or restoring other degraded human functions.

### SUMMARY OF THE INVENTION

A nanolaminate structure is made of Al₂O₃/TiO₂ multilayered thin films and an oxide layer preferably at the interface between the top electrode and the nanolaminate. The nanolaminate thin films have individual layer thicknesses in the range of about 0.1 to 1 nm and beyond, as required to achieve the combined properties of giant dielectric constant (k=100-1000 or higher), low leakage current, and low losses for extended frequency range operation. The combined properties mentioned above are achieved by inserting an Al₂O₃, or in selected cases can be achieved by inserting another oxide (e.g., HfOₓ, BaOₓ, TaOₓ, NbOₓ, etc.) at the interface of the Al₂O₃/TiO₂ nanolaminate with a metallic (e.g., Pt, Ti, W, or any other metal) bottom and/or top contact layers to produce capacitor-like structures. Such structures can be used in several new technologies for which the giant-k dielectric Al₂O₃/TiO₂ nanolaminate provides a critical component, namely: 1) as a gate oxide for the new generation of nanoscale CMOS transistors for integrated circuits in nanoelectronics; 2) as a dielectric layer for fabrication of high-capacitance capacitors embedded in microchips implantable in the human body (using the biocompatible properties of Al₂O₃ and TiO₂ films); 3) as a dielectric layer for fabrication of high-capacitance capacitors for energy storage systems; 4) as a nanoscale insulator layer for magnetic multilayer memory devices; and 5) for any other application where an atomic scale thick layer with high-dielectric constant is required. A great advantage of the Al₂O₃/TiO₂ nanolaminates is that the individual layers are amorphous, thus being much simpler and less costly to produce on different substrates used for the fabrication of devices. The Al₂O₃/TiO₂ nanolaminates with the interfacial Al₂O₃ layer at the nanolaminate/metallic contact layer solve the problem of the high leakage/losses and limited frequency range operation of the nanolaminates without the interfacial Al₂O₃ layer, thus making the nanolaminates suitable for commercial devices.

These and other advantages and features of the invention, together with the organization and manner of operation thereof, will become apparent from the following detailed description when taken in conjunction with the accompanying drawings.

### BRIEF DESCRIPTION OF THE DRAWINGS

FIG. 1 shows a schematic of a field effect CMOS transistor with a critical gate oxide layer;

FIG. 2(a) shows a schematic of a metal-insulator capacitor structure including a TAO (Al₂O₃/TiO₂) nanolaminate structure as a dielectric layer; FIG. 2(b) shows a bright field TEM image of a reference TAO sample; and FIG. 2(c) shows a Ti-map obtained from an energy filtered TEM image including line scans calculated from an elemental map of Ti;

FIG. 3(a) shows a high resolution cross-section TEM image of the TAO nanolaminate with 0.5 nm thick individual layers of Al₂O₃ and TiO₂; FIG. 3(b) and FIG. 3(c) show, respectively, a high resolution TEM image and a corresponding schematic image of a series of Al₂O₃/TiO₂ nanolaminate structures;

FIG. 4(a) shows dielectric constant versus frequency; FIG. 4(b) shows loss vs. frequency; FIG. 4(c) shows leakage current density vs. applied voltage as a function of a thickness of the additional Al₂O₃ layer on top of the TAO nanolaminate; FIG. 4(d) shows combined dielectric constant and loss at 100 Hz, and leakage current density at 1 V as a function of the thickness of the top Al₂O₃ layer on TAO nanolaminate (the top Al₂O₃ layer thickness was determined by the summation of the additional Al₂O₃ layer thickness and 0.5 nm of Al₂O₃ layer in TAO); and

FIG. 5(a) shows a schematic of various positions of additional Al₂O₃ layer to the TAO nanolaminate structure; FIG. 5(b) shows leakage current density vs. applied voltage; FIG. 5(c) shows dielectric constant versus frequency as a function of the position of the additional Al₂O₃ layer to the TAO nanolaminate structure; and FIG. 5(d) shows loss versus frequency as a function of the position of the additional TiO₂ layer to the TAO nanolaminate structure.

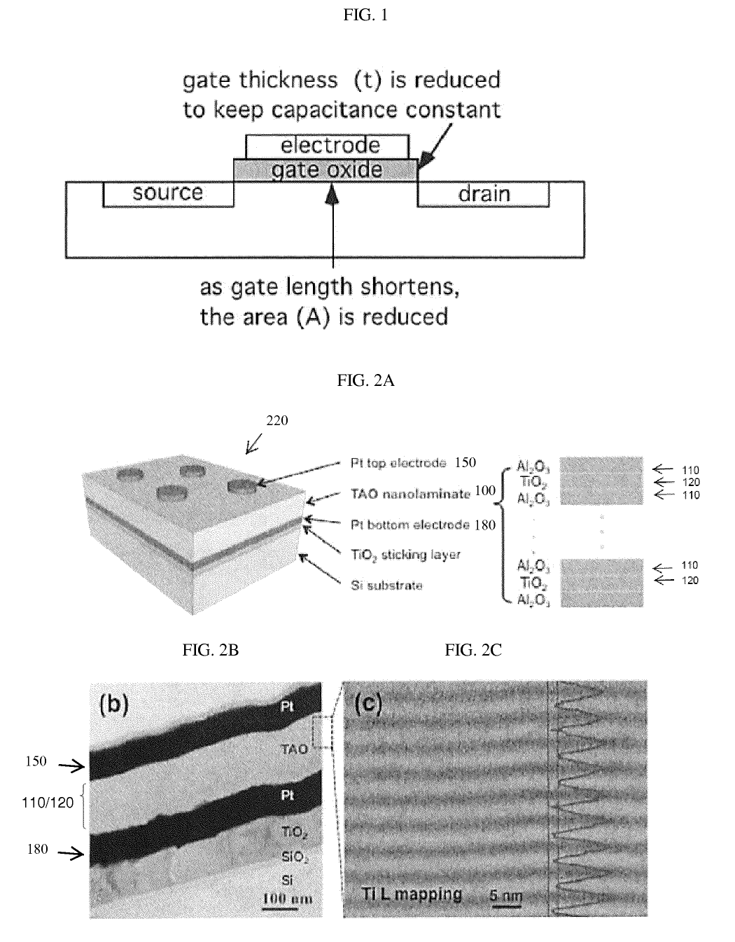

### DETAILED DESCRIPTION OF PREFERRED EMBODIMENTS

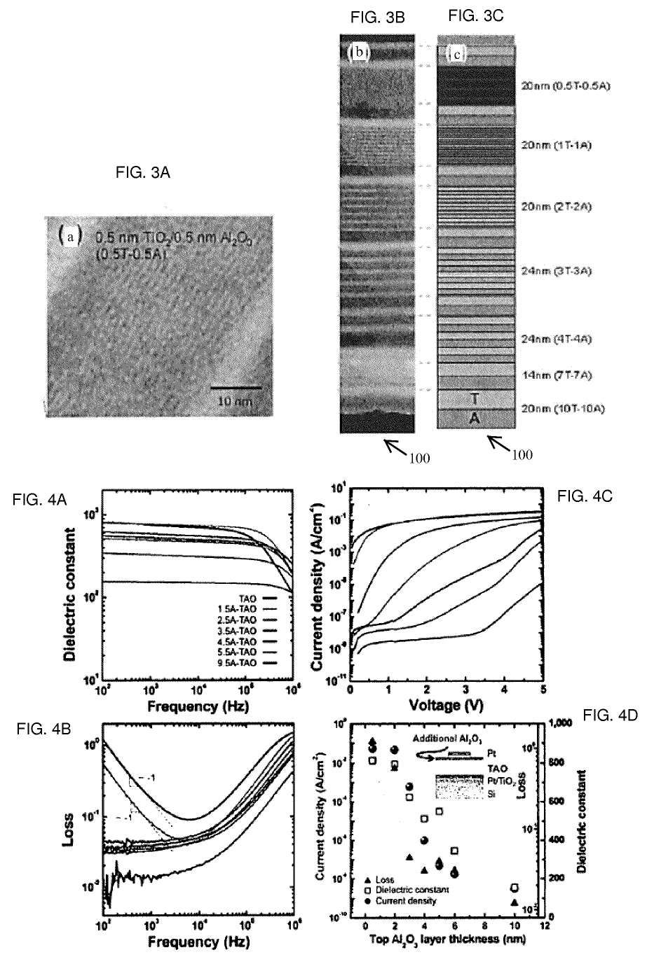

FIGS. 2(a), 2(b), 3(a) and 3(b) show a nanolaminate structure 100 having a plurality of Al₂O₃/TiO₂ thin films 110/120 having layer thicknesses of about 0.1-1 nm, although greater nm thicknesses can also be used, provided combined properties of the nanolaminate structure 100 achieve a giant dielectric constant of k−100-1000 or higher, low leakage currents and low losses for extended frequency range operation.

In addition to the application for the next generation of nanoscale CMOS devices, the new Al₂O₃/TiO₂ nanolaminates 110/120 can include an interfacial Al₂O₃ layer 140 to provide a reliable dielectric layer for microchip embedded capacitors for implantable biomedical devices, and for high capacitance capacitor for energy storage systems, and for other future applications requiring high-k dielectric layers with all the properties shown for the new nanolaminates reported here.

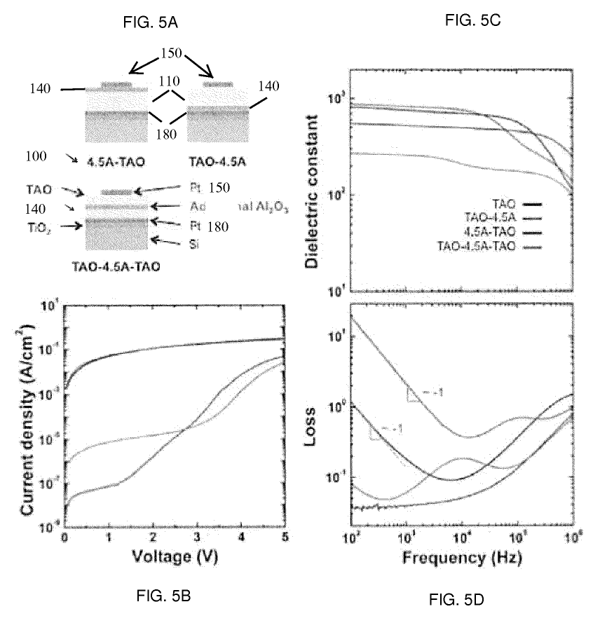

In one preferred embodiment shown in FIG. 5(a) the Al₂O₃/TiO₂ nanolaminate structure 100 comprises alternating 0.5 nm thick TiO₂ and 0.5 nm thick Al₂O₃ sublayers (hereinafter, TAO) synthesized by atomic layer deposition, and include most preferably a 5 nm thick form of the Al₂O₃ interfacial layer 140 at a nanolaminate/top electrode contact 150 (hereinafter, “the top electrode contact”). The nanolaminate structure 100 exhibits a high dielectric constant (>550) with significantly low loss (<0.04) and leakage current density (<10⁻⁷ A/cm² up to 1.0 V). Without limiting the scope of the invention, the unusually high dielectric constant is attributed to the Maxwell-Wagner relaxation between conducting TiO₂ and insulating Al₂O₃, while the low loss and low leakage current density are likely due to blockage of leakage current by the Al₂O₃ interfacial layer 140 at the top electrode contact 150.

The Al₂O₃/TiO₂ nanolaminate structure 100 is preferably grown using atomic layer deposition (ALD), which is the technique capable of growing films with atomic layer precision. All layers were grown at 300° C., although lower temperatures (100-200° C.) can also produce the Al₂O₃/TiO₂ nanolaminates. The ALD process uses trimethylaluminum [Al(CH₃)₃] and titanium tetrachloride (TiCl₄) as Al and Ti precursors, respectively, and H₂O as the oxidant.

For the preferred Al₂O₃/TiO₂ nanolaminate structure 100, 5 cycles of Al₂O₃ and 15 cycles of TiO₂ sublayers were deposited alternately to achieve equal sublayer thicknesses of 0.5 nm. A reference Al₂O₃/TiO₂ nanolaminate was used to precisely elucidate the effect of the Al₂O₃ interfacial layer the between Al₂O₃/TiO₂ nanolaminate structure 100 and the top electrode contact 150. Nanolaminates with additional layers associated with the top electrode contact 150, a middle layer 170, and a bottom Al₂O₃ interfacial electrode contact 180 can be referred to as A-TAO, TAO-A-TAO, and TAO-A, respectively. Therefore, for example, 4.5A-TAO designates that a 4.5 nm thick Al₂O₃ interfacial layer 140 is deposited adjacent the top electrode contact 150 of the reference TAO nanolaminate structure 100. A Pt form of the top electrode contact 150 and the bottom electrode contact 180 can be grown by RF-magnetron sputtering, electron beam evaporation, or atomic layer deposition for both the bottom and top electrode contact 150, using a shadow mask to define a circular or any other geometrical shape of the top Pt electrodes 150 and 180; thickness and diameter (defined by a shadow mask) of the top electrode contact 150 was 100 nm and 250 mm, respectively. Alternatively, the patterned top electrodes can be produced by growing a blanket metal film on the nanolaminate and then do lithography and reactive ion etching (RIE) to define the geometry and dimensions of the electrodes. X-ray diffraction (XRD, Philips X-Pert 8856) and Transmission Electron Microscopy (TEM, FEI Tecnai F20ST TEM/STEM) revealed that the Al₂O₃ and TiO₂ layers of the nanolaminate structure 100 are amorphous. Dielectric properties were measured using an Agilent 4294A precision impedance analyzer at room temperature. The leakage current was measured using a Keithley 237 unit.

FIG. 2(a) illustrates a representative Pt/TAO/Pt capacitor nanolaminate structure 220 on a TiO₂-coated Si substrates 230. A reference TAO nanolaminate structure 100 was terminated by 0.5 nm thick top and bottom Al₂O₃ interfacial layers 140 with a symmetric layered structure, as depicted in FIG. 2(a). FIG. 2(b) shows a cross-sectional TEM image of the nanolaminate structure 220 as such an example capacitor. No discernable crystalline phases in the reference TAO structure 240 were detected by selected area electron diffraction in TEM, as well as by XRD (data not shown). Alternating Al₂O₃ and TiO₂ sublayers 110 and 120, respectively, and their compositional variation, using Ti X-ray L line as the trace, are shown in high-resolution TEM images and component mapping, respectively, in FIG. 2(c).

FIG. 3(a) shows a high resolution cross-section TEM image of the TAO nanolaminate structure 220 with 0.5 nm thick individual layers of the Al₂O₃ layer 110 and the TiO₂ layer 120; FIGS. 3 (b) and (c) show high resolution TEM images and corresponding schematics of images of a series of the Al₂O₃/TiO₂ nanolaminate layers 110/120 with different individual layer thickness, produced to determine the optimum structure to achieve the highest dielectric constant and the lowest leakage current and losses needed for commercial devices.

The effects of top Al₂O₃ interfacial layers 140 on dielectric constant, loss, and leakage current density of the TAO nanolaminates 100 are shown in FIG. 4. Similar to prior results, a reference TAO nanolaminate 100 without an Al₂O₃ (A) interfacial layer 140 showed very high dielectric constant (>800) in the frequency range of 100 Hz ˜10 kHz, high leakage current density (˜10⁻¹ A/cm² at 1 V) and high loss (>0.1 in 100 Hz 1 MHz), plotted as black lines in FIGS. 4(a)-(c). The dielectric constant of TAO nanolaminates 100 with an “A” interface layer 140 (A-TAO) at the electrode/Al₂O₃ interface remains high (>500), when the thickness of the additional Al₂O₃ layer 140 is less than 4.5 nm (FIG. 4 (a)). However, the insertion of the Al₂O₃ interfacial layer 140 at the top electrode 150 interface produces a dramatic reduction in loss and leakage. FIG. 4(b) shows that the Al₂O₃ top layer 140 that is only 2.5 nm thick reduces the dielectric loss from >1.0 to <0.05 in the low frequency region. The most significant effect of the additional Al₂O₃ interface layer 140 at the top electrode contact 150/TAO nanolaminate 100 interface is shown in FIG. 4 (c), six orders of magnitude reduction in leakage current density at 1.0 V (i.e., from ˜10⁻¹ to ˜10⁻⁷ A/cm²) is produced with an additional 4.5 nm thick Al₂O₃ top layer (i.e., 4.5A-TAO). Trends of dielectric constant and loss at 100 Hz, and leakage current density at 1.0 V are plotted in FIG. 4 (d). Increasing the thickness of the Al₂O₃ interfacial layer 140 results in a gradual decrease of the dielectric constant, while the loss and leakage current density decrease exponentially. Therefore, the adequate additional thickness of the Al₂O₃ interfacial layer 140 for optimizing the dielectric properties of the TAO nanolaminates 100 is in the range of 2.5 to 5.5 nm. In particular, it was found that the 4.5 nm thick Al₂O₃ interfacial layer 140 can significantly reduce the leakage current density (<10⁻⁷ A/cm² when voltage <1.5 V) and loss (<0.04 when f<10 kHz) while maintaining high dielectric constant (>600 when f<100 kHz).

It was observed that a 1.5 nm Al₂O₃ interfacial layer 140 is too thin to block leakage current between a top electrode contact 150 and the dielectric interfacial film layer 140. Such behavior is likely related to conduction mechanisms of ALD Al₂O₃ ultrathin films reported in the art (but such suppositions are not meant to limit the claims) wherein direct tunneling occurred when ALD Al₂O₃ ultrathin interfacial films 140 are thinner than 2.5 nm. It is also reported that the dielectric strength of the ALD Al₂O₃ ultrathin films 140 could reach ˜10 MV/cm when deposited on very smooth conductive substrates. In the case, of the dielectric interfacial films 140 discussed herein, since the substrate has been coated with sputtered polycrystalline Pt films, thus exhibiting surface roughness larger than the conventional atomic scale roughness of a Si surface, the thickness of the ALD Al₂O₃ film 140 that can effectively reduce tunneling seems to be 3.5 nm. This is probably due to high electric fields developed on nanoscale asperities resulting from the sputter-deposition process of Pt films. To further reduce the tunneling current (<10⁻⁷ A/cm² at 1 V), it is necessary to increase the thickness of the Al₂O₃ interfacial layers 140 approximately to >4.5 nm.

The following non-limiting examples illustrate various aspects of the invention.

### EXAMPLES

In order to optimize the effect of the Al₂O₃ interfacial layer, experiments were performed to determine the optimum position of the Al₂O₃ interfacial layer, considering effects of surface roughness or sputter-deposition-induced topography during the electrode layer growth. In this respect, studies focused on determining the effect of inserting the 4.5 nm thick Al₂O₃ interfacial layer at different positions in the TAO nanolaminates, as schematically depicted in FIG. 5 (a). The structures investigated were: (i) 4.5A-TAO (4.5 nm Al₂O₃ interfacial layer on the top of TAO at the top Pt electrode/TAO interface), (ii) TAO-4.5A (4.5 nm interfacial Al₂O₃ layer at the bottom Pt electrode/TAO interface), and (iii) TAO-4.5A-TAO (4.5 nm interfacial Al₂O₃ layer in the middle of TAO structure). FIG. 5 (b) shows the leakage current density of all three TAO nanolaminates described above, including the reference TAO. The TAO-4.5A still exhibits high current density, similar to the reference TAO. In contrast, the leakage current density of TAO-4.5A-TAO and 4.5A-TAO is dramatically reduced. Because the top electrode was deposited by rf-magnetron sputter-deposition, energetic species from the plasma were created in front of the target to induce the sputtering process, thus there was ejection of Pt atoms for subsequent deposition on the TAO layer. The energetic plasma species can impact on the TAO surface, producing damage that can be destructive on the TAO film during the deposition process. Without limiting the scope of the invention, this defective interface and high surface energy state can contribute to high leakage current density. The insertion of a highly insulating and suitably thick Al₂O₃ layer on top of the TAO, however, likely can minimize or eliminate the defective surface state of the TAO film from the sputtering process and reduce the leakage current density effectively, as shown in FIG. 5 (b). The effect of the sputter-induced damage effect mentioned above was tested by growing the top Pt electrode using electron beam (e-beam) evaporation, which involves deposition of Pt atoms with ≦1 eV bombardment energy.

The capacitor structures produced with the top Pt electrode deposited by e-beam evaporation result in substantial less leakage current density (not shown here) than that of the electrode produced by sputter-deposition. On the other hand, for the case of insertion of the Al₂O₃ interfacial layer at the bottom electrode (TAO-4.5A), it does not make a big difference because the interface is very rough as seen in FIG. 2 (b) and large comparative to that of the top electrode. Therefore, it is difficult to prevent the charge injection by inserting the 4.5 nm thick bottom Al₂O₃ interface layer. In this respect, the Al₂O₃ layer in the middle of TAO (TAO-4.5A-TAO), as insulating layer, can have a medium effect compared with the layers inserted at the between top and bottom electrode interfaces. The possibility exists for minimizing the effects of electrode interface roughness by growing the bottom and top electrodes using ALD.

The present invention has the potential of providing a whole new generation of nanoelectronic devices, which require high-k dielectric layers with the combined properties demonstrated for the Al₂O₃/TiO₂ nanolaminates. The high dielectric constant TAO nanolaminates also provide the basis for new embedded supercapacitors in a new generation of microchips implantable in the human body, due to the biocompatibility of TiO₂ and Al₂O₃. Also, the TAO-based supercapacitors can provide a new generation of energy storage systems. Because the component layers are biocompatible, these nanolaminates provide a broad range of applications to both non-biologically and biologically compatible devices and systems.

The foregoing description of embodiments of the present invention has been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments, and with various modifications, as are suited to the particular use contemplated.

1. A capacitor comprising:
a top electrode;
a bottom electode;
a nanolaminate layer positioned between the bottom electrode and the top electrode, the naonolaminate layer comprising alternating layers of Al₂O₃ and TiO₂, the nanolaminate layer further comprising an interfacial layer.

2. The capacitor of claim 1, wherein each of the alternating layers of Al₂O₃ and TiO₂ has a thickness of about 0.1 nm to about 1 nm.

3. The capacitor of claim 1, wherein the interfacial layer comprises Al₂O₃.

4. The capacitor of claim 3, wherein the interfacial layer is positioned between the top electrode and the alternating layers of Al₂O₃ and TiO₂.

5. The capacitor of claim 3, wherein the interfacial layer is positioned within the alternating layers of Al₂O₃ and TiO₂.

6. The capacitor of claim 3, wherein the alternating layers of Al₂O₃ and TiO₂ begin with a Al₂O₃ layer and end with a Al₂O₃ layer.

7. The capacitor of claim 1, wherein the interfacial layer has a thickness of about 1 nm to about 10 nm.

8. The capacitor of claim 1, wherein the bottom electrode and the top electrode consist essentially of platinum containing materials.

9. The capacitor of claim 1, further comprising a substrate layer.

10. The capacitor of claim 1 having a dielectric constant greater than about 150, loss of less than about 0.02, and leakage current density of less than about 10⁻⁸ A/cm².

11. A nanolaminate structure comprising:
alternating layers of Al₂O₃ and TiO₂ each of the alternating layers having a thickness of about 0.1 to 1 nm, and
an interfacial layer having a thickness of about 1 nm to about 10 nm.

12. The nanolaminate structure of claim 10, wherein the interfacial layer comprises Al₂O₃.

13. The nanolaminate structure of claim 12, wherein the interfacial layer is positioned on top of the alternating layers of Al₂O₃ and TiO₂.

14. The nanolaminate structure of claim 12, wherein the interfacial layer is positioned within the alternating layers of Al₂O₃ and TiO₂.

15. A nanolaminate capacitor comprising:
a substrate layer,
an adhesion layer adhered to the substrate layer on a first side;
a bottom electrode adhered to the adhesion layer on a second side;
a Al₂O₃ and TiO₂ nanolaminate layer comprising a plurality of alternating layers of Al₂O₃ and TiO₂, each of the alternating layers having a thickness of about 0.1 nm to about 1 nm; and
an interfacial layer disposed between a top electrode and the bottom electrode.

16. The capacitor of claim 15, wherein the interfacial layer comprises Al₂O₃

17. The capacitor of claim 15, wherein the interfacial layer is positioned between the top electrode and the plurality of alternating layers of Al₂O₃ and TiO₂.

18. The capacitor of claim 15, wherein the interfacial layer is positioned within the plurality of alternating layers of Al₂O₃ and TiO₂.

19. The capacitor of claim 15, wherein the interfacial layer has a thickness of about 1 nm to about 10 nm.

20. The capacitor of claim 15 having a dielectric constant greater than about 150, loss of less than about 0.02, and leakage current density of less than about 10⁻⁸ A/cm².
